(19) United States
(12) Patent Application Publication
(10) Pub. No.: US 2015/0177282 A1
(43) Pub. Date: Jun. 25, 2015

(54) METHOD, APPARATUS AND SYSTEM FOR COLLECTION AND DISPLAY OF HOUSEHOLD POWER USAGE

(71) Applicants: Bertrand Wendling, Divonne Les Bains (FR); Charles M. Fish, New Hope, PA (US); Joel Wenger, Etoy (CH)

(72) Inventors: Bertrand Wendling, Divonne Les Bains (FR); Charles M. Fish, New Hope, PA (US); Joel Wenger, Etoy (CH)

(21) Appl. No.: 14/134,581

(22) Filed: Dec. 19, 2013

(51) Int. Cl. G01R 19/00; G05B 15/02

(52) U.S. Cl. CPC G01R 19/00; G05B 15/02

(57) ABSTRACT

A method and apparatus for collecting household power usage within a media gateway. An energy usage indicator is received from various electrical loads within a household using a home area network. The media gateway is communicatively coupled to the various electrical loads by means of the home area network. The energy usage indicator is incorporated into a media stream developed by the media gateway. This media stream is then disseminated to media devices within a household for display to user. Further, the energy usage indicator is conveyed to a central service which collects additional energy usage indicators and generates an energy usage guideline. The energy usage guideline is returned to the media gateway and also incorporated into the media stream to enable a user to make informed decisions about energy apportionment amongst various electrical loads in a household.

### BACKGROUND

Household energy consumption is becoming a major drain on economic resources. The modern household now includes many different devices that require electrical power. Because of this, it is becoming of paramount importance to understand electrical usage profiles within the home. There are in fact many systems that display real-time energy consumption for different devices in a home. Typically, these prior art systems rely on power measurement devices that are typically disposed at a utility power distribution panel. In some other power measurement systems, power measurement devices are distributed throughout a home, for example by means of smart electrical outlets disposed throughout a dwelling.

Most of these prior art systems collect energy usage on an ongoing basis and attempt to create profiles that described energy usage for different devices within the home over the course of a particular period of time. For example, such prior art systems typically profile for a homeowner the amount of energy used over a particular week or month. As this type of information is gathered, most such energy logging systems will create comparison charts so that a homeowner can appreciate how energy consumption varies from month-to-month or from year to year. As such, a homeowner can then determine if particular appliances are using too much energy and a homeowner can then adjust usage patterns in order to save on electrical costs. Of course, the homeowner could use such energy usage information to identify ineffective appliances that may be in the home. For example, where an air conditioner is using far too much power when compared to prior years.

As sophisticated as these prior art systems may be, at the least they leave the onus upon the homeowner to determine what is and what is not excessive energy usage. For example, the homeowner must determine if his refrigerator is using too much electricity. And where devices are used on an on-demand basis, again the homeowner must determine if a television is being used to frequently. Sundry other appliances, for example hairdryers and toaster ovens, also utilize energy and their power usage can be tracked in a similar way. Again, it is up to the individual homeowner to establish his own guidelines as to how much electricity should be devoted to a particular appliance over a particular period of time.

There may in fact be some advantage to knowing how much electricity each particular appliances in a home ends up using over a particular month and in understanding how such usage varies according to seasons, perhaps or some other periodicity. Unfortunately, most homeowners are already probably overwhelmed with information and substantially powerless to optimize the usage of electricity in their home even if such usage statistics were provided by prior art energy consumption monitoring systems. And, unless there is some motivation which can be appreciated by the homeowner, beyond a few kilowatt-hours of electricity savings on the monthly power bill, most homeowners are likely to ignore energy usage statistics in deference to more important matters in managing their households. Home owners also need usable and useful tools to manage the described information overload.

With the advantage of modern digital signal processing technology and ever diminishing prices for integrated silicon chips, some proponents are uniting to create even more intelligent appliances for use inside each home. This is a dramatic paradigm shift from prior art technologies where energy consumption is collected in an almost “afterthought like” manner. In this newly developing realm of technology, the communications interface is included in an appliance along with energy metering capability. As such, the appliance itself can convey energy usage directly to a smart meter using various communication technology. For example, one system uses power line communications that provided for digital data communication directly through household electrical wiring. In this system a communications connection is established when the electrical apparatus is plugged into a convenience outlet. This dramatically simplifies the burden on a homeowner because the appliance registers with the smart meter as soon as the communications link is established. And, as already noted, the communications link is established as soon as the appliance is plugged into a utility outlet.

In Europe, an appliance interworking specification has been promulgated. This appliance interworking specification establishes physical and functional protocols for devices to communicate electricity usage and other information amongst themselves and smart meters. It is in this new technology realm that energy management within a home can be effectively realized. For example, the refrigerator can now register with a display panel and provide real-time power usage information which can not only be displayed, but also analyzed by a smart control panel situated in the home. It has even been suggested that such a smart control panel could provide not only electrical usage information from within the home but also present the homeowner with neighborhood averages for electricity use.

It has also been suggested that electrical usage information can also be displayed on other media devices situated in the home. For example, a media center could access the information provided by various appliances within the home and then present that information on a television screen. Electrical usage information and appliance control can also be established through smart phones and thermostats. Unfortunately, there seems to be known teaching as to how such display and control functions would be best implemented across a myriad of dissimilar devices.

All of this hoped for interoperability is great in concept but is exceedingly difficult to realize in practice. It is one thing to suggest a particular function, but suggesting a functional capability and actually detailing how it is implemented seems to be the chasm which no one has been able to bridge. Even if there were a home area network that is compliant with an actual and applied appliance interworking specification, there is still no suggestion as to how appliances should or could share information to the greater good, in this case reducing overall energy consumption within the home.

Existing literature does nothing more than suggest a concept of “press and play” where appliances connected by means of a home area network facilitate energy awareness and a plethora of new services which might be enjoyed by a homeowner. Sadly, it seems that the only functions now realized are those of controlling appliances on a master control panel. The fact that the same control panel is used to present electricity usage information to a homeowner is fortuitous, but only from the standpoint that the same control point can be used for both functions. What is lacking is a means to exploit the information received from energy aware appliances and other more traditional power measurement points situated within the home and to present this information, together with tools and suggestions to a homeowner in a manner that would enable the homeowner to easily establish criteria and actions for local energy conservation.

### BRIEF DESCRIPTION OF THE DRAWINGS

Several alternative embodiments will hereinafter be described in conjunction with the appended drawings and figures, wherein like numerals denote like elements, and in which:

FIG. 1 is a pictorial diagram that depicts one illustrative application of the present method, apparatus and system for displaying energy usage information for electrical loads situated within a household;

FIG. 2 is a flow diagram that depicts one illustrative method for collecting household power usage within a dwelling;

FIG. 3 is a flow diagram that depicts one alternative example method for receiving a first energy usage indicator;

FIG. 3A is a flow diagram that depicts alternative methods for receiving energy usage indicator;

FIG. 4 is a flow diagram that depicts yet another alternative method for receiving a first energy usage indicator;

FIG. 5 is a flow diagram that depicts one alternative example method for creating an energy usage guideline;

FIG. 5A is a flow diagram that depicts one alternative method for presenting an energy usage guideline and receiving an adjustment to a corresponding energy allocation;

FIG. 6 is a flow diagram that depicts yet another alternative method for developing an energy usage guideline;

FIG. 7 is a pictorial diagram that depicts application of the present method within a particular use scenario, for example amongst a plurality of dwellings;

FIG. 8 is a block diagram that illustrates one illustrative embodiment of an apparatus for collecting and displaying power usage information; and

FIG. 9 is a data flow diagram that depicts the interaction of various modules as they are executed by a processor included in an apparatus for collecting and displaying power usage information; and

FIG. 10 is a pictorial diagram that depicts one example embodiment of a graphical representation of an energy guideline and allocation for a load.

### DETAILED DESCRIPTION

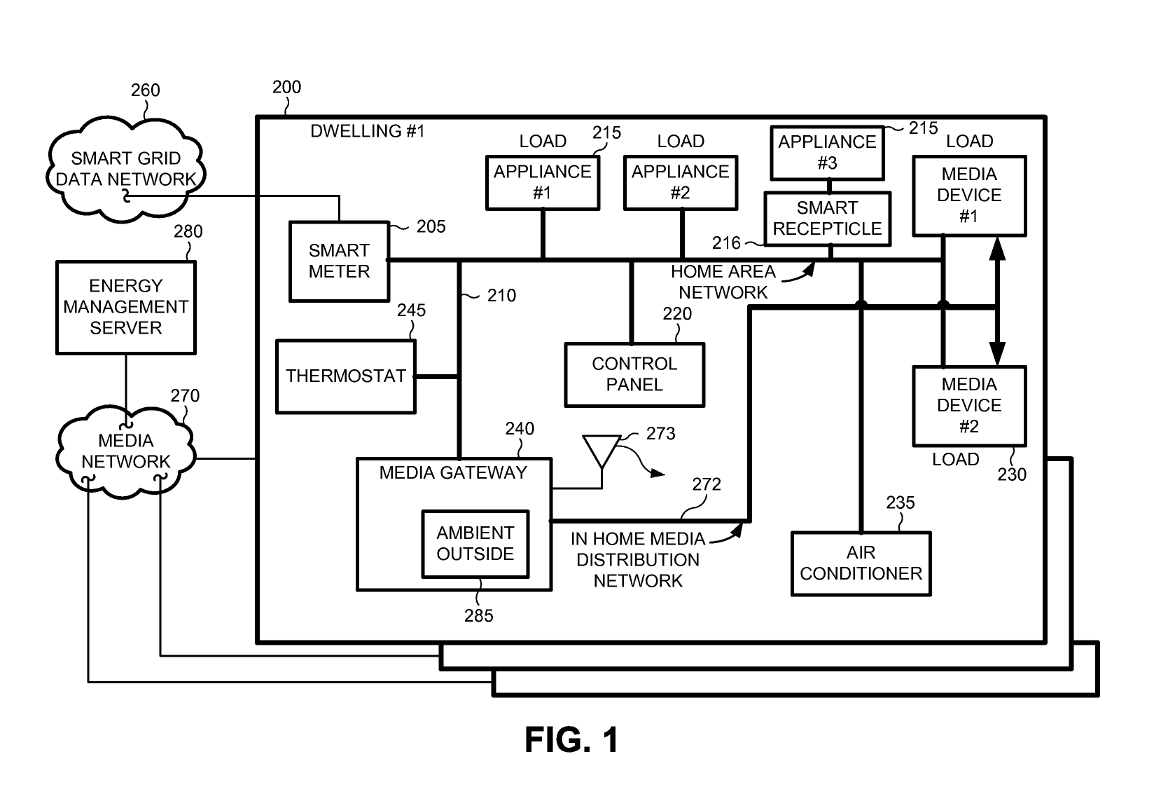

FIG. 1 is a pictorial diagram that depicts one illustrative application of the present method, apparatus and system for displaying energy usage information for electrical loads situated within a household. In one illustrative use case, a dwelling 200 includes one or more loads that provide useful functions to the inhabitants of the dwelling 200. It should be appreciated that electrical loads may include various functional devices. For example appliances such as refrigerators, dishwashers, washing machines for laundry and dryers for laundry are just some of the types of electrical loads 215 that might be included in a dwelling 200. The dwelling 200 may also have disposed within it various media devices 230. Of course, we cannot forget to mention that a dwelling 200 is more than likely to have situated therein or proximate to an air-conditioning system 235 that provides comfortable air to the dwelling.

In one illustrative use case, electrical loads within the dwelling 200 communicate power usage information to a metering unit 205. It should be appreciated that, according to this illustrative use case, the electrical loads include some form of metering apparatus and a communication interface. In yet another illustrative use case, these electrical loads comprise “energy aware appliances” as described thus far described. In yet another illustrative use case, the communication interface included in an electrical load comprises a power line communication interface that communicates digital information by way of household electrical wiring 210. In yet another illustrative use case, the electrical loads 215 are connected to the electrical wiring 210 by means of a “smart receptacle”. A smart receptacle includes a power metering capability and a communications capability. Accordingly, the power provided to an electrical load by way of such a smart receptacle is measured and said measurement is communication to the home area network 210. In a functional sense, the electrical wiring 210 serves as a media for the home area network that is itself intended to communicate electrical usage information from the electrical loads to the metering devices 205. It should be appreciated that the terms “home area network” and the “electrical wiring” within the home are used interchangeably in this disclosure.

Since the metering device 205 is also attached to the household electric wiring 210 it is clear that electrical usage information from each of the loads may be readily communicated to the metering device 205. In one alternative illustrative use case, the metering device comprises a smart meter which is itself communicatively coupled to a smart grid electrical distributional system 260 and the data network associated therewith.

In currently known systems, power usage information available on the home area network 210 is displayed to a user by means of a control panel 220. In yet another illustrative use case, the control panel 220 facilitates control of each of the electrical loads attached to the communication interface. Where an air-conditioner 235 is disposed within the dwelling 200, a thermostat 245 may optionally utilize the home area network 210 in order to control the air-conditioner 235. All of these illustrative use cases are presented for illustration purposes only and these illustrative use cases are not intended to limit the scope of the claims appended hereto.

Up until now, usage information from a particular dwelling may have been collected by a utility company in order to understand the loading on the power distribution grid 260. Even though this information is available by way of the smart grid 260, individual homeowners may not have the proper facilities to access this data. Although most utility companies will allow users access to this data, the data is rarely in a form that can be presented to a user in a reasonable format. Accordingly, a control panel 220 that is communicatively coupled to the household electrical wiring 210 receives the same electrical usage information from the various loads disposed within the dwelling 200. The control panel 220 then organizes the electrical usage information into relevant formats and presents this information to a user, e.g. a homeowner.

There are in fact sophisticated control panels 220 then enable the user to establish power usage limitations for each of the electrical loads within the dwelling 200. However, as already discussed, the information presented to the user may not necessarily be comprehensible vis-a-vis the task of establishing electrical usage limits for such electrical loads.

FIG. 1 further depicts that electrical usage information available on the home area network, according to one example embodiment of a method, apparatus and system for displaying electrical usage information to a user, is collected in a media gateway 240. In this example embodiment, the media gateway 240 receives the electrical usage information and presents this information at various media devices 230 disposed within the dwelling 200. It should be appreciated that this is commonly accomplished by the use of an in-home media distribution network 272. In yet another alternative example embodiment, the media gateway 240 communicates the electrical usage information for a particular dwelling 200 to a management server 280. In one alternative example embodiment, the management server 280 is communicatively coupled to the media gateway 240 by means of a wide area media distribution network 270.

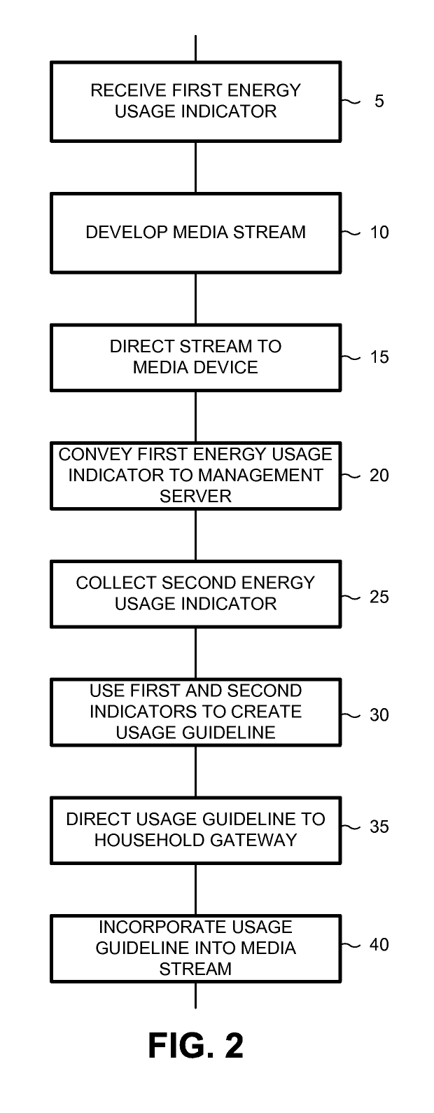

FIG. 2 is a flow diagram that depicts one illustrative method for collecting household power usage within a dwelling. In this example method, electrical usage information is received in the form of a first energy usage indicator (step 5). It should be appreciated that, according to one alternative method, this first energy usage indicator is received into a household media gateway. Once the energy usage indicator is received, a media stream is developed (step 10). This media stream reflects electrical usage information included in the first energy usage indicator. The developed media stream is then made available (step 15) to media devices disposed within the dwelling. It should be appreciated that additional energy usage indicators, according to yet another alternative method, are collected from other electrical loads within the household and are likewise incorporated into the media stream before it is made available to the media devices disposed within the dwelling.

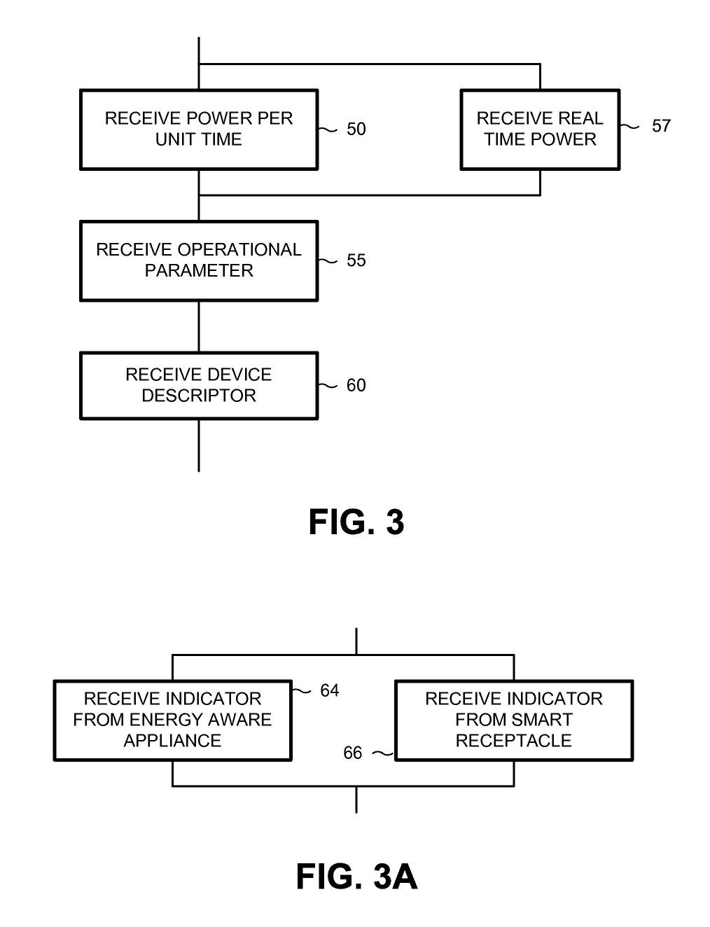

FIG. 3 is a flow diagram that depicts one alternative example method for receiving a first energy usage indicator. In this alternative example method, a first energy usage indicator is received by first receiving an indicator for “power used per-unit time” (step 50). For example, a particular electrical load may be using a particular amount of power per-unit time. A refrigerator, for example, may have consumed 10 kilowatts in the last hour. In yet another alternative example method, a first energy usage indicator is received by first receiving an indicator of instantaneous power use (step 57). Of course these are merely examples and the scope of the claims appended hereto or not intended to be limited to any such example presented.

In this alternative example method, the first energy usage indicator is received by next receiving an operational parameter indicator (step 55). In this alternative example method, an operational parameter indicator may include a wide variety of parameters associated with a particular electrical load. In yet another alternative example method, an operational parameter may include some real-time indication of performance. The refrigerator again serves as an adequate example where an operational parameter comprises an internal temperature for the refrigerator's cooling chamber. In yet another alternative example method, the refrigerator also provides, as an operational parameter, an ambient temperature value that reflects the temperature external to the cooling chamber. Again these are merely illustrative examples and are not meant to limit the scope of the claims appended hereto.

In yet another alternative example method, receiving a First energy usage indicator further comprises the step of receiving a device descriptor (step 60). Such device descriptor may in fact reflect the internal volume of a refrigerator. For example a particular refrigerator may provide 30 cubic feet of volume within its cooling chamber. In yet another alternative example, the device descriptor comprises a model number for the device associated with the first energy usage indicator. Again the refrigerator example adequately demonstrates that a model number for a particular refrigerator may be used to determine other physical and functional characteristics of the device for which a first energy usage indicator is received. These examples are meant to illustrate what a device descriptor comprises and are not intended to limit the scope of the claims appended hereto.

FIG. 3A is a flow diagram that depicts alternative methods for receiving an energy usage indicator. As already discussed in respect to one illustrative use case, an energy usage indicator is presented to the home area network by an energy aware appliance. As such, one alternative method for receiving an energy usage indicator comprises receiving such an energy usage indicator from an energy aware appliance (step 64). In yet another alternative use case, the energy usage indicator is sourced by a smart receptacle. Such a smart receptacle includes a power metering capability and a networking capability and is typically disposed between the home power wiring and a load receiving power from t he home power wiring. Accordingly, an alternative method for receiving an energy usage indicator comprises receiving an energy usage indicator from a smart receptacle (step 66).

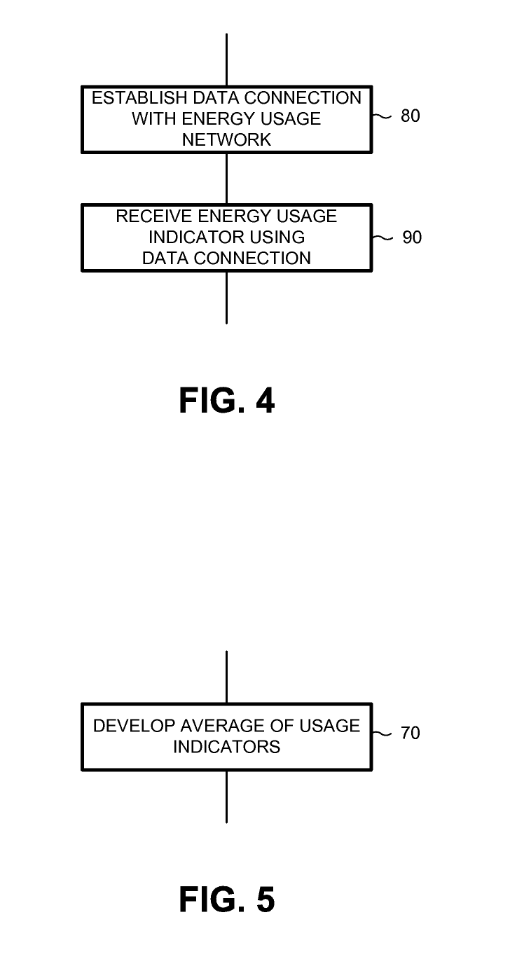

FIG. 4 is a flow diagram that depicts yet another alternative method for receiving a first energy usage indicator. It should be appreciated that energy usage indicators are available within the dwelling and are carried by a home area network. In this alternative example method, receiving a first energy usage indicator comprises a first step of establishing a data connection with an energy usage network (step 80). For example, a home area network intended to communicate energy usage information is included in the class of networking within a home otherwise described as an energy usage network. Once data communication is establish with the energy usage network, energy usage indicators are received by means of the data connection (step 90). This in fact may be accomplished in several different ways. For example, in one alternative example method, energy usage information in the form of energy usage indicators is received by simply monitoring the energy usage network and passively capturing energy usage indicators. In yet another alternative example method, energy usage information is obtained by establishing data connections with each of the loads attached to the energy usage network. In this case, specific communication for retrieving energy usage indicators from each of the loads attached to the energy usage network is utilized.

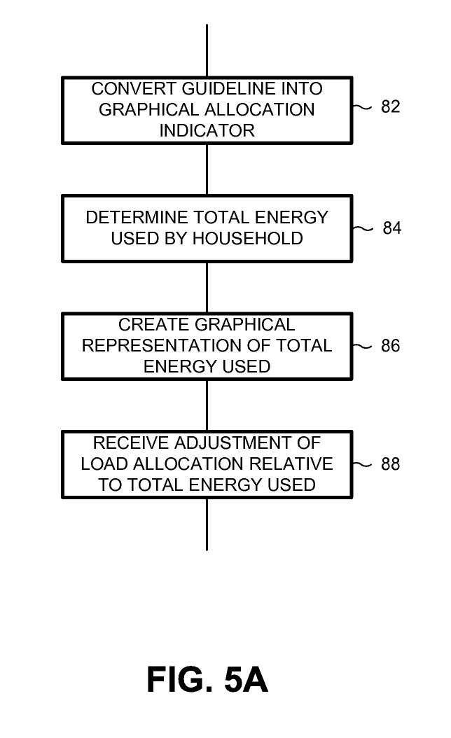

FIG. 5 is a flow diagram that depicts one alternative example method for creating an energy usage guideline. In this example alternative method, the energy usage guideline is created by developing an average of the usage indications reflected in one or more energy usage indicators. Typically, this is accomplished according to a particular type of energy using device (e.g. an appliance). In yet another example alternative method, a device descriptor included in an energy usage indicator is used to categorize energy usage indicators into compatible load types. Accordingly, energy usage indicators for compatible load types are then used to create an energy usage guideline for a particular load type. Again, in yet another alternative example method, an energy usage guideline is developed according to compatible load types as identified by device descriptors included in energy usage indicators and the energy usage indicators are then used to develop an average value, which is then disseminated as an energy usage guideline for a particular load type.

FIG. 5A is a flow diagram that depicts one alternative method for presenting an energy usage guideline and receiving an adjustment to a corresponding energy allocation. In this alternative example method, the step of incorporating an energy guideline into a media stream comprises converting the guideline into a graphical allocation indicator (step 82). In this alternative example embodiment, the graphical allocation indicator is sized in proportion to a total amount of energy used in a household. In order to perform this sizing, this example method also provides for determining the total energy usage in the household (step 84). It should be appreciated that determining the total energy usage in a household, according to one alternative example method, is accomplished by receiving one or more energy usage indicators from the home area network over a period of time and then extrapolating those values to determine power used over a longer period of time into the future. In yet another alternative method, determining the total energy usage in a household is accomplished by receiving a historical usage value for a particular period of time.

Once the total amount of energy is determined, a graphical representation is made according thereto. Again, the graphical representation is proportionally scaled together with the graphical allocation indicator. The graphical representation of total energy used, in this alternative example method, includes a sub-indicator that is initially set to also represent the graphical allocation indicator for a load. This sub-indicator is adjustable by a user using normal graphical user interface techniques including at least one of resizing the sub-indicator to adjust the amount of energy should be allocated to the load relative to the total energy used. Accordingly, this adjustment is used to control the amount of energy consumed by a load by adjusting operating parameters for the load. In the example of a refrigerator, the internal temperature may be adjusted to conform with a newly adjusted energy allocation for the refrigerator as subject to other restrictions that may be imposed by the user.

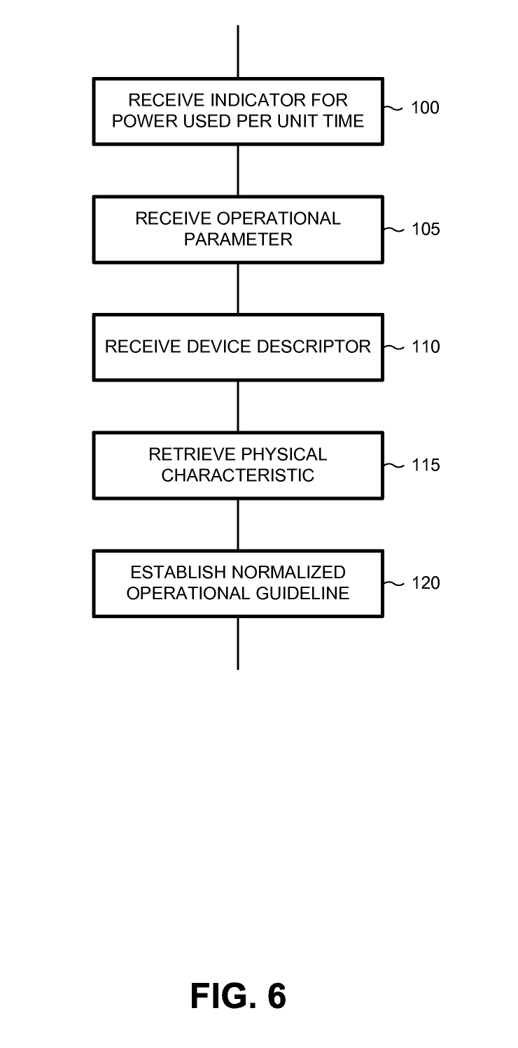

FIG. 6 is a flow diagram that depicts yet another alternative method for developing an energy usage guideline. According to this alternative example method, an energy usage guideline is developed by receiving an indicator for power used per-unit time (step 100). Again, as an example, a particular appliance may utilize 10 kilowatts in the prior one hour of operation. Typically, a timestamp is included in such a power used indicator. In this example method, an operational parameter is also received (step 105). For example, an operational parameter may include internal operating temperature or external ambient temperature. For example, the efficiency of a refrigerator may be represented by the amount of power use to maintain a particular differential between internal operating temperature of a refrigerated chamber and the ambient environment surrounding the refrigerator. Hence, in one alternative example method, an energy usage guideline is represented in terms of the amount of power used in order to achieve a particular operational parameter. Again, by example, a refrigerator may utilize 10 kilowatts per hour in order to maintain a 30 degree Celsius differential between its internal refrigerated chamber and the external environment. In yet another example, efficiency of an air-conditioning system may be represented by the amount of power used in order to maintain a differential temperature gradient between the comfort region of a home and the outside environment.

According to this alternative example method, a device descriptor is also received (step 110). A physical characteristic is then retrieved (step 115) according to the device descriptor. Then, a normalized operational guideline is established (step 120) according to the physical characteristic, the operational parameter and the power used per-unit time. Again, such normalize operational guideline is represented, according to this example method, as an amount of energy required to achieve a particular operational parameter.

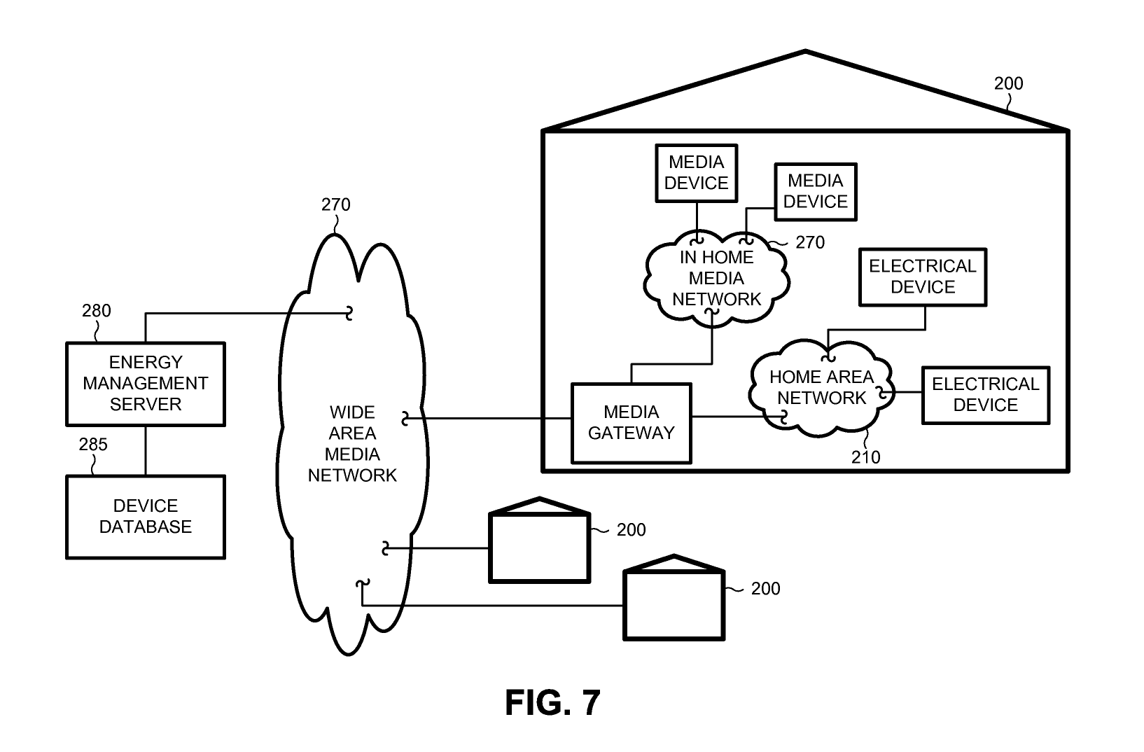

FIG. 7 is a pictorial diagram that depicts application of the present method within a particular use scenario, for example amongst a plurality of dwellings. It is helpful to consider FIG. 7 in conjunction with FIG. 1. It should be appreciated that the present method, apparatus and system are intended to be used to promote energy awareness and conservation on a wide scale. In one particular use scenario, a plurality of dwellings 200 is connected to a wide area network for media distribution 270. Accordingly, the media distribution network 270 is used to distribute media content to the plurality of dwellings 200 and to enable communications with an energy management server 280. In one particular application, energy usage indicators received from the individual dwellings 200 are conveyed by means of the wide area media distribution network 270 to the energy management server 280. It should be appreciated that, according to one alternative example application, dwellings 200 from within a particular geographical region are considered collectively when the energy management server 280 creates energy usage guidelines. Hence, energy usage guidelines are peculiar to a particular geographic region.

In yet another illustrative application, operational parameters from a particular energy load are used in accordance with power usage indications and other physical characteristics to create energy usage guidelines that are particular to a particular load type. For example, a particular class of washing machine may in fact have energy usage characteristics that can be compared across a very wide geographic region. In fact, it is the particular class of washing machine and the operational parameters in play that are also important in comparing energy usage for that particular class of appliance.

It should hence be appreciated that the energy management server 280 is communicatively coupled to a device database 285 which is used to store information on particular devices and which is accessed according to a device descriptor received as part of an energy usage indications from a particular device within a dwellings 200. In this alternative example illustrative use case, the energy management server 280 includes a capability for creating an energy usage guideline. In this example embodiment of an energy management server 280, a second energy usage indicator is received film a different dwelling 200 and a first energy usage indicator is received from a first dwelling 200. These disparate energy usage indicators are then used to generate an energy usage guideline according to the teachings of the present method.

In this example embodiment, the energy management server 280 disseminates the energy usage guideline to the plurality of dwellings 200 using the wide area media distribution network 270. In yet another illustrative example use case, an alternative embodiment of an energy management server 280 receives energy usage indicators from the plurality of dwellings 200. The energy management server 280 then organizes the energy usage indicators according to device descriptors included in said energy usage indicators. Accordingly, in this alternative example embodiment of an energy management server 280, energy usage indicators are then directed to the dwellings 200 when a dwelling 200 has contained therein a device of comparable load characteristics. For example, an energy usage indicator as received from a dwelling for a particular class of laundry dryer will then be directed to other dwellings to have a comparable class of laundry dryer.

In yet another illustrative se scenario, the wide area network for media distribution 270 is disposed in order to service the particular geographic region within which are disposed a particular plurality of dwellings 200. In this illustrative use scenario, when one dwelling 200 conveys an energy usage indicator to the wide area media network 270, all other dwellings 200 receive that energy usage indicator and will then utilize that receives energy usage indicator to create energy usage guidelines.

It should be appreciated that, according to the foregoing illustrative applications, an energy usage indicator from one dwelling 200 is usable for the purposes of increasing energy conservation by other dwellings 200. As can be appreciated, this can be accomplished in numerous ways. In one alternative example method, homeowners are allowed to opt-in or opt-out of a service which shares their energy usage information with other dwellings. Likewise, in another alternative method, a homeowner is incentivized to participate in the sharing of energy usages information through offers of at least one of receiving energy usages information from other homeowners, energy rebates from utility companies, and charitable contributions made on their behalf.

As already described, a plurality of energy usage indicators may be received in the energy management server 280 and the energy management server then creates an energy usage guideline which is then shared with the dwellings. In other illustrative use cases, energy usage indicators are shared amongst all of the dwellings and each dwelling is then responsible for generating its own energy usage guideline. It should be appreciated that a system for creating and sharing energy usage guidelines may thus be embodied in numerous ways and the foregoing examples are not intended to limit the scope of the claims appended hereto.

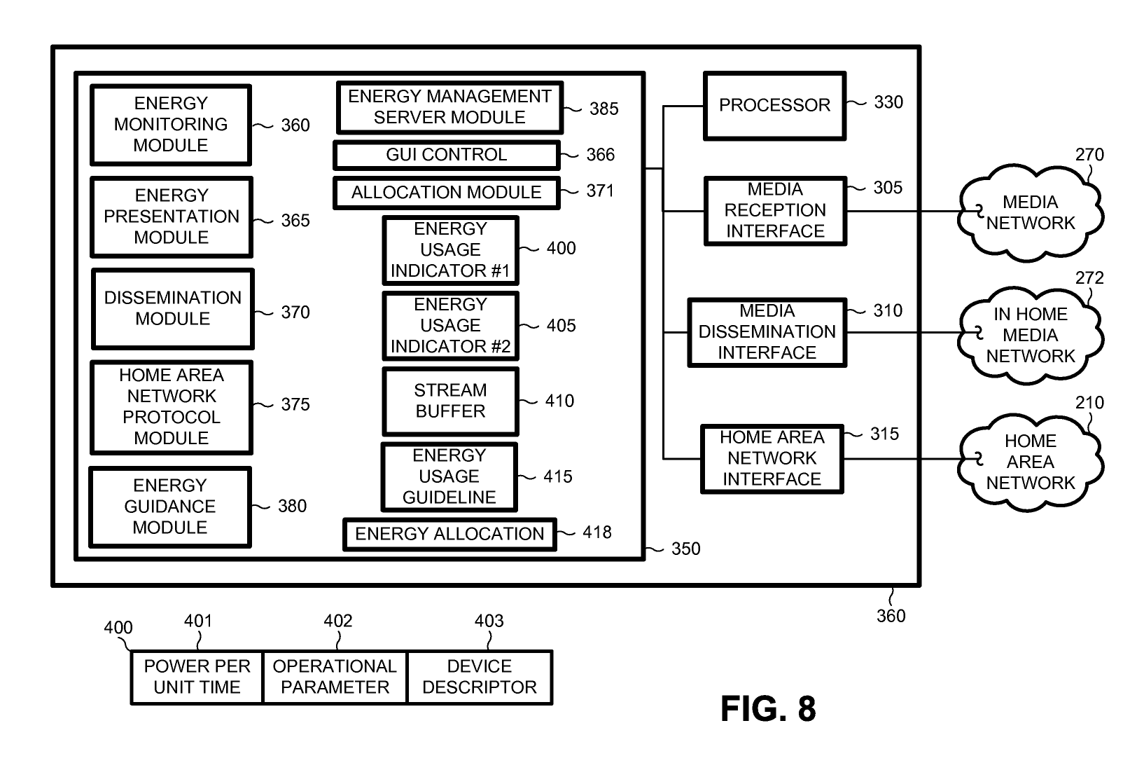

FIG. 8 is a block diagram that illustrates one illustrative embodiment of an apparatus for collecting and displaying power usage information. According to this illustrative example embodiment, an apparatus 300 for collecting and displaying power usage information comprises a media reception interface 305. The media reception interface 305 is typically used to receive media content from a media distribution network 270. This example embodiment of an apparatus 300 for collecting and displaying power usage information further comprises the media dissemination interface 310. The media dissemination interface 310 is typically used to interface with an in-home media network 272. The in-home media network 272 is then used to convey media to media devices within a dwelling. This example embodiment of an apparatus for collecting and displaying power usage information 300 also further comprises a home area network interface 315. The home area network interface 315 is typically used to interact with a home area network 210 for the purpose of receiving energy usage indicators from a power consuming device attached to the home area network 210. This example embodiment further comprises a processor 330 and a memory 350.

Further included in this example embodiment are various functional modules each of which comprises an instruction sequence. For purposes of this disclosure, a functional module and its corresponding instruction sequence is referred to by a process name, a function name or a module name, each of which may be used interchangeably. The instruction sequence that implements the process name, according to one alternative embodiment, is stored in the memory 350. The reader is advised that the term “minimally causes the processor” and variants thereof is intended to serve as an open-ended enumeration of functions performed by the processor 330 as it executes a particular functional process (i.e. instruction sequence). As such, an embodiment where a particular functional process causes the processor to perform functions in addition to those defined in the appended claims is to be included in the scope of the claims appended hereto.

As already described, the memory 350 is used to store various functional modules. The memory 350 is also used to store various elements of information including a first energy usage indicator 400, a second energy usage indicator 405, a media stream buffer 410, and an energy usage guideline 415.

In one example embodiment, an apparatus 300 for collecting and displaying power usage information further includes an energy monitoring module 360, an energy presentation module 365 and a dissemination module 370, each of which are stored in the memory 350. In yet another alternative example embodiment, the apparatus 300 for collecting and displaying power usage information further includes a home area network protocol module 375, which is also stored in the memory 350. And, in yet another alternative example embodiment, an apparatus 300 for collecting and displaying power usage information further includes an energy management server module 385, which is also stored in the memory 350.

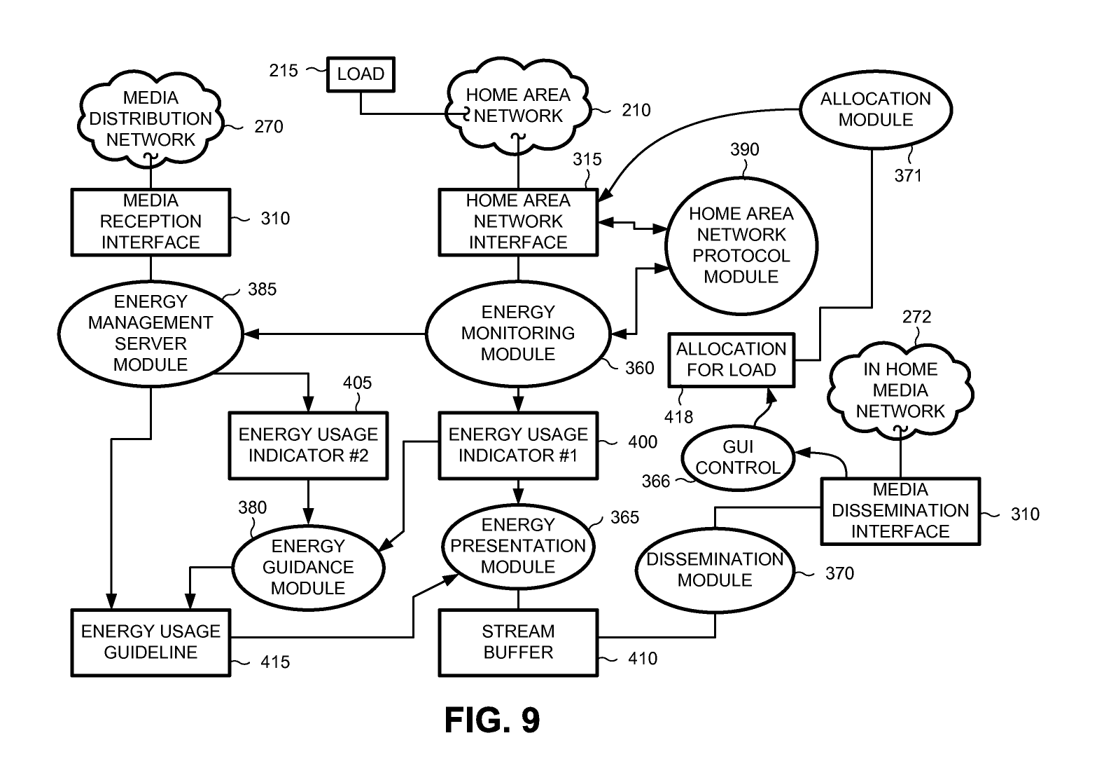

FIG. 9 is a data flow diagram that depicts the interaction of various modules as they are executed by a processor included in an apparatus for collecting and displaying power usage information. In one alternative example embodiment, the processor 330, as it executes the energy monitoring module 360, is minimally causes to receive an energy usage indicator by means of a home area network interface 315. Once the processor 330 receives the energy usage indicator, the energy monitoring module 360, as executed by the processor 330, further minimally causes the processor 330 to store the energy usage indicator in the memory 350. Typically, the energy usage indicator is stored in an energy usage indicator variable 400. This is the case for a first energy usage indicator received by the processor 330 by means of the home area network interface 315.

As the processor continues to operate, it then begins to execute the energy presentation module 365. The energy presentation module 365, when executed by the processor 330, minimally causes the processor 330 to create a media stream based upon the energy usage indicator 400 stored in the memory 350. It should be appreciated that, according to one example embodiment, the processor 330, as it continues to execute the energy presentation module 365, is minimally causes to create a media stream and to store said stream in a stream buffer 410, which is stored in the memory 350. The dissemination module 370, which is also executed by the processor 350, minimally causes the processor 350 to direct the media stream from the stream buffer 410 to the media dissemination interface 310. The media dissemination interface 310 then directs the media stream to the in-home media distribution network 272, from which media devices included in the dwelling may obtain the media stream that includes the energy usage information.

In one alternative example embodiment, the energy monitoring module 360, as it is executed by the processor 330, minimally causes the processor 330 to receive an indicator for power usage per unit time along with an operational parameter indicator and a device descriptor. In this alternative example embodiment, processor 330 stores this information in an energy usage indicator variable 400 which includes a power per unit time data element 401, an operational parameter data element 402 and a device descriptor data element 403.

FIG. 9 further depicts that, according to yet another alternative example embodiment, an apparatus 300 for collecting and displaying power usage information further comprises a home area network protocol module 390, which is used to in order to establish a data connection with an energy aware appliance 215. In this example embodiment, the home area network interface 315 is used as media attachment to the home area network 210. Accordingly, the similar interface is included in the energy aware appliance 215. Once a data connection is established, the data connection is used to receive an energy usage indicator from the energy aware appliance 215 by means of the home area network interface. Again, this is accomplished as the processor 330 executes the home area network protocol module 390.

And yet another alternative example of embodiment, an apparatus 300 for collecting and displaying power usage information further comprises an energy management server interface module 385, which is also stored in the memory 350. In this example alternative embodiment, the processor 330, as it begins to execute the energy management server interface module 385, is minimally caused to receive a second energy usage indicator by means of the media reception interface 310. In this case, and energy guidance module 380, included in this alternative example embodiment of an apparatus 300 for collecting and displaying power usage information, as it is executed by the processor 330, minimally causes the processor 330 to create an energy usage guideline using the second usage indicator 405 and the first energy usage indicator 400. The energy usage guideline is stored in memory in an energy usage guideline data structure 415.

It to be appreciated that, according to yet another alternative example embodiment, the energy monitoring module 360, as it is executed by the processor 330, further minimally conveys a device descriptor to the energy management server module 385. Accordingly, the energy management server module 385, as it is executed by the processor 330, further minimally causes the processor 330 to convey the device descriptor to the media reception interface 310. In one illustrative use case, the device descriptor is forwarded to an energy management server 280. The energy management server 280 then returns a second usage indicator, when said second usage indicator is for energy loads that are of compatible type according to the device descriptor.

In yet another alternative example embodiment, the energy guidance module 380, when executed by the processor 330, minimally causes the processor 330 to create an energy usage guideline by creating an average of the first energy usage indicator 400 and the second energy usage indicator 405. The energy usage guideline 415 is then incorporated into a media stream as the processor continues to execute the energy presentation module 365.

In yet another alternative example embodiment, the energy management server module 385, as it is executed by the processor 330, minimally causes the processor 330 to receive an energy usage guideline directly from the media reception interface 310. In one illustrative use case, the energy usage guideline is received from an energy management server 280 by means of the media reception interface 310. In this alternative example embodiment, the energy usage guideline is stored in an energy usage guideline data structure 415 that is stored in the memory. The energy presentation module 365, as it is executed by the processor 330, incorporates the energy usage guideline stored in the energy usage guideline data structure 415 into a media stream, which is stored in the stream buffer 410. Accordingly, the processor 330, as it continues to execute the dissemination module 370, directs the content of the stream buffer 410 to the media dissemination interface 310.

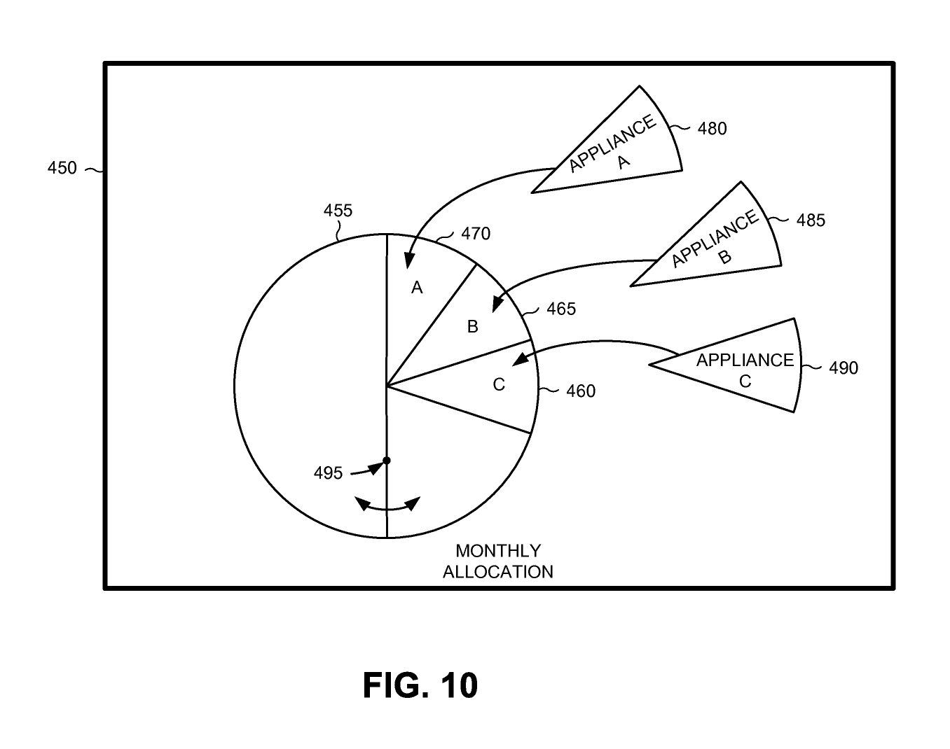

FIG. 10 is a pictorial diagram that depicts one example embodiment of a graphical representation of an energy guideline and allocation for a load. In this example embodiment, a graphical image 450 is created by the processor 330 as it executes the energy presentation module 365. As the processor 300 executes the energy presentation module 365, it creates a graphical representation of a total amount of energy to be consumed by a dwelling over a particular period of time. The processor, as it executes the energy presentation module 365, then retrieves an energy usage guideline 415 for a particular load. The processor 330 then creates a graphical representation of the energy usage guideline.

In this example embodiment of an energy presentation module 365, the processor 330 creates an energy usage guideline in the form of a pie-shaped graphic 480. It should be appreciated that various such pie shaped graphics may be created according to a plurality of energy usage guidelines retrieved from the memory 350. In this example embodiment, the processor 330 also creates in the memory corresponding pie shaped controls to be included in a substantially circular representation of total monthly allocation of energy 455. The controls the controls 460, 465 and 470 corresponds to graphical representations of energy usage guidelines 480, 485 and 490. It should be appreciated that the graphical controls, according to one alternative embodiment, and include one or more handle points 495. A user may adjust the energy allocation for a particular load by dragging the handle point 495 angularly about the center of the substantially circular representation of total energy usage 455.

In yet another alternative embodiment, an apparatus 300 for collecting and displaying power usage information further comprises a gooey control module 366 and an allocation module 371, both of which are stored in the memory 350. The memory 350 is also used to store and allocation variable 418 for a particular load. As a user adjusts a control 460, the graphical user interface control module 366 recognizes the motion of a pointing device on the screen upon which graphical representations described herein are presented. Accordingly, as the processor 330 then adjusts an allocation variable 418 for that particular load, said energy allocation variable 418 being stored in the memory 350. In this alternative example embodiment, the processor 330 also executes the allocation module 371.

The allocation module 371, when executed by the processor 330, causes the processor 330 to retrieve from the memory 350 the allocation value 418 set for a particular load tends to direct the allocation value to the load itself by way of the home area network interface 315. Thus, a user has a graphical representation not only of the total amount of energy that should be allocated for a particular period, for example a month or a week or any other suitable period of time, but also has a graphical representation of an energy guideline for a particular load and is then able to adjusts an allocation for that particular load relative to the guideline and relative to the total monitor energy to be utilized within the dwelling for a particular period of time.

The functional processes (and their corresponding instruction sequences) described thus far that enable characterization of a network connection are, according to one embodiment, imparted onto computer readable medium. Examples of such media include, but are not limited to, random access memory, read-only memory (ROM), CD ROM, data versatile disks, flash memory, floppy disks, and magnetic tape. This computer readable media, which alone or in combination can constitute a stand-alone product, can be used to convert a general-purpose computing platform into a device for collecting and displaying power usage information according to the techniques and teachings presented herein.

While the present method, apparatus, computer-readable medium and system have been described in terms of several alternative methods and embodiments, it is contemplated that alternatives, modifications, permutations, and equivalents thereof are to be included in the scope of the appended claims.

1. A method for collecting household power usage comprising:
receiving into a household media gateway a first energy usage indicator;
developing a media stream according to the first energy usage indicator; and
disseminating the media stream to media devices disposed within a household.

2. The method of claim 1 wherein receiving a first energy usages indicator comprises:
receiving an indicator for power used per unit time;
receiving an operational parameter indicator; and
receiving a device descriptor.

3. The method of claim 1 wherein receiving a first energy usages indicator comprises:
establishing a data connection with a home area network used to communicate power usage data from an energy aware electrical apparatus; and
receiving an energy usage indicator my means of the data connection.

4. The method of claim 1 further comprising:
conveying the first energy usage indicator to a management server;
collecting a second energy usages indicator from a different household;
developing an energy usage guideline according to the first and second energy usage indicators;
directing the energy usage guideline to the household media gateway; and
incorporating the energy usage guideline into the media stream.

5. The method of claim 4 wherein the step of developing an energy usage guideline comprises establishing an average based on the first and second energy usage indicators.

6. The method of claim 4 wherein the step of incorporating the energy usage guideline into the media stream comprises:
converting the guideline into a graphical representation of an energy allocation for a load represented by the first energy usage indicator;
determining a total energy usage for the household; and
creating a graphical control for adjusting the amount of energy to be allocated to the load relative to the total energy usage for the household.

7. The method of claim 4 wherein the step of developing an energy usage guideline comprises:
receiving an indicator for power used per unit time;
receiving an operational parameter indicator; and
receiving a device descriptor and wherein the step of developing an energy usage guideline comprises:
retrieving a physical characteristic for a device according to the received device descriptor; and
establishing a normalized guideline for the device according to the physical characteristic, the operational parameter and the power used per unit time indicator.

8. The method of claim 1 wherein the step of receiving an energy usage indicator comprises receiving an energy usage indicator from at least one of an energy aware appliance and a smart receptacle. An apparatus for collecting and displaying power usage information comprising:
a home network interface compatible with a home power usage communications network;
media reception interface for receiving media content;
media delivery interface for disseminating media content;
processor capable of executing an instruction sequence;
memory capable of storing information and one or more instruction sequences; and
one or more instruction sequences stored in the memory including:
energy monitoring module that, when executed by the processor, minimally causes the processor to receive an energy usage indicator by way of the home network interface and to store said energy usage indicator in the memory;
energy presentation module that, when executed by the processor, minimally causes the processor to develop a media stream according to the energy usage indicator stored in the memory; and
dissemination module that, when executed by the processor, minimally causes the processor to direct the media stream to the media delivery interface.

9. The apparatus of claim 8 wherein the energy monitoring module, when executed by the processor, minimally causes the processor to:
receive an indicator for power used per unit of time;
receive an operational parameter indicator; and
receive a device descriptor.

10. The apparatus of claim 8 further comprising a home area network protocol module and wherein the energy monitoring module, when executed by the processor, minimally causes the processor to execute the home area network protocol module which, when executed by the processor, minimally causes the processor to:
use the home area network interface to establish a data connection with an energy aware appliance and where the energy monitoring module further minimally causes the processor to use the established data connection to receive an energy usage indicator.

11. The apparatus of claim 8 further comprising:
energy management server interface module that, when executed by the processor, minimally causes the processor to:
receive a second energy usage indicator using the media reception interface; and
energy guidance module that, when executed by the processor, minimally causes the processor to create an energy guideline according to the first and second energy usage indicators
and wherein the energy presentation module further minimally causes the processor to:
incorporate the energy usage guideline into a media stream created according to an energy usage indicator stored in the memory.

12. The apparatus of claim 11 wherein the energy guidance module, when executed by the processor, minimally causes the processor to create an energy guideline based on an average of the first and second energy usage indicators.

13. The apparatus of claim 8 further comprising:
management server interface module that, when executed by the processor, minimally causes the processor to:
convey a first energy usage indicator to a management server using the media reception interface; and
receive an energy usage guideline from the management server using the media reception interface
and wherein the energy presentation module further minimally causes the processor to:
incorporate the energy usage guideline into a media stream created according to an energy usage indicator stored in the memory.

14. The apparatus of claim 8 wherein the energy presentation module minimally causes the processor to develop a media stream by minimally causing the processor to:
create in the memory a graphical representation of a total amount of energy used for a period of time;
create in the memory a graphical representation of an energy allocation for a load; and

15. retrieve from the memory the graphical total energy representation and the graphical energy allocation and incorporate said graphical total energy representation and graphical energy allocation into a media stream. A computer readable medium having imparted thereon instruction sequence that enable a general purpose processor to collect and display power usage information including:
energy monitoring module that, when executed by a processor, minimally causes the processor to receive an energy usage indicator from a load and to storm the energy usage indicator in a memory;
energy presentation module that, when executed by the processor, minimally causes the processor to create a media stream that includes a graphical representation of the energy usage indicator stored in a memory; and
dissemination module that, when executed by the processor, minimally causes the processor to direct the media stream to a media delivery interface.

16. The computer readable medium of claim 15 wherein the energy monitoring module, when executed by the processor, minimally causes the processor to:
receive an indicator for power used per unit of time;
receive an operational parameter indicator; and
receive a device descriptor.

17. The computer readable medium of claim 15 further comprising a home area network protocol module and wherein the energy monitoring module, when executed by the processor, minimally causes the processor to execute the home area network protocol module which, when executed by the processor, minimally causes the processor to:
use a home area network interface to establish a data connection with an energy aware appliance and where the energy monitoring module further minimally causes the processor to use the established data connection to receive an energy usage indicator.

18. The computer readable medium of claim 8 further comprising:
energy management server interface module that, when executed by the processor, minimally causes the processor to:
receive a second energy usage indicator using a media reception interface; and energy guidance module that, when executed by the processor, minimally causes the processor to create an energy guideline according to the first and second energy usage indicators
and wherein the energy presentation module further minimally causes the processor to:
incorporate the energy usage guideline into a media stream created according to an energy usage indicator stored in the memory.

19. The computer readable medium of claim 11 wherein the energy guidance module, when executed by the processor, minimally causes the processor to create an energy guideline based on an average of the first and second energy usage indicators.

20. The computer readable medium of claim 8 further comprising:
management server interface module that, when executed by the processor, minimally causes the processor to:
convey a first energy usage indicator to a management server using a media reception interface; and
receive an energy usage guideline from a management server using a media reception interface
and wherein the energy presentation module further minimally causes the processor to:
incorporate the energy usage guideline into a media stream created accord to an energy usage indicator stored in the memory.

21. An apparatus for collecting and displaying energy usage data comprising:
means for receive an energy usage indicator from an electrical load;
means for generating a media stream according to the energy usage indicator; and
means for distributing the media stream to a collection of media devices.

22. The apparatus of claim 19 further comprising:
means for directing the energy usage indicator to an energy management server;
means for receiving an energy usage guideline from the energy management server; and
means for incorporating the energy usage guideline into the media stream.
